(19) United States
(12) Patent Application Publication
(10) Pub. No.: US 2008/0303110 A1
(43) Pub. Date: Dec. 11, 2008

(54) Integrated circuit package and method for operating and fabricating thereof

(75) Inventor: Po-Han Lee, Taoyuan (TW)

Correspondence Address: BIRCH STEWART KOLASCH & BIRCH, PO BOX 747, FALLS CHURCH, VA, 22040-0747, US

(73) Assignee: XinTec Inc.

(21) Appl. No.: 11/892,118

(22) Filed: Aug. 20, 2007

(30) Foreign Application Priority Data
Jun. 11, 2007 (TW) 96120950

(51) Int. Cl. H01L 31/0203; H01L 21/02

(52) U.S. Cl. 257/434; 438/64; 257/E31.093; 257/E21.598

(57) ABSTRACT

The invention provides an integrated circuit package and method for operating and fabricating thereof. The package comprises a transparent substrate having a first surface and a second surface opposite to each other and a semiconductor layer formed on the second surface of the transparent substrate. A photosensitive device is fabricated on the semiconductor layer and a metal plug is formed over the second surface of the transparent substrate and they are electrically connected to each other. A solder ball is formed over the second surface of the transparent substrate and electrically connected to the metal plug. In the package, the photosensitive device senses light penetrating the transparent substrate and the semiconductor layer through its backside to produce a signal which is subsequently transmitted to solder ball by the metal plug. Thus, the signal conductive path is shortened. Moreover, the photosensitive device is directly formed on the semiconductor layer without extra steps, for example bonding and notching, fabrication processes are reduced. Thus, fabrication cost is reduced.

### BACKGROUND OF THE INVENTION

1. Field of the Invention

The invention relates to integrated circuit packages, and in particular relates to an integrated circuit package having reduced dimensions and a method of fabrication thereof.

2. Description of the Related Art

The integrated circuit device fabrication process includes a packaging step. The fabricated integrated circuit device is utilized in a wide variety of applications, including computers, mobile phones and digital cameras. Specifically, the integrated circuit package fabrication plays an important role in the resulting dimensions and performance of the integrated circuit device.

Referring to FIG. 1, a cross section of a conventional integrated circuit package is shown. In FIG. 1, a silicon substrate 2, on which a photosensitive device 4 and an extension pad 6 are formed thereon and electrically connected to each other, is provided. Next, a transparent covering plate 10 is bonded to the silicon substrate 2 followed by attachment of the silicon substrate 2 to a carrying substrate 8. Following, a conductive layer 12 is extended from the sidewalls of the carrying substrate 8 to the extension pad 6 to electrically connect the photosensitive device 4 to a solder ball 14.

For the described package in FIG. 1, the silicon substrate 2 and the carrying substrate 8, both have a certain thickness, result in a relatively thick package with large dimensions. Moreover, fabrication and design of the metal plug (not shown) is restricted due to the position of a metal plug disposed on the same side as the sensitive surface of the photosensitive device 4. Additionally, since the conductive layer is disposed close to an exterior portion of the package, for example the sidewalls of the substrates, damage to the conductive layer may occur during the fabrication process and cause failure in the package.

Thus, an integrated circuit package and fabrication method thereof eradicating or minimizing the described problems is needed.

### BRIEF SUMMARY OF INVENTION

Accordingly, the invention provides an integrated circuit package. An exemplary embodiment of the package comprises a transparent substrate having a first surface and a second surface opposite to each other; a semiconductor layer formed on the second surface of the transparent substrate; a photosensitive device formed on the semiconductor layer; a metal plug formed over the second surface of the transparent substrate and electrically connected to the photosensitive device; and a solder ball formed over the second surface of the transparent substrate and electrically connected to the metal plug. For the package, a signal produced by the photosensitive device can be transmitted to the solder ball by the metal plug rather than by a conductive layer located on the sidewalls of the substrates. Thus, the conductive path of the signal is shortened. Moreover, because the metal plug for transmitting the signal is formed inside the package, the probability of damage to the conductive path during fabrication is reduced. Furthermore, because the package is fabricated without an extra carrying plate and silicon substrate, thus decreasing thickness, the dimensions of the package are reduced.

Also, the invention provides a method for fabricating an integrated circuit package. The method comprises providing a transparent substrate having a first surface and a second surface opposite to each other; forming a semiconductor layer on the second surface of the transparent substrate; forming a photosensitive device on the semiconductor layer; forming a metal plug over the second surface of the transparent substrate and electrically connected to the photosensitive device; and forming a solder ball over the second surface of the transparent substrate and electrically connected to the metal plug. According to the method, fabrication steps and costs are reduced because the photosensitive device is fabricated directly on the semiconductor layer on the transparent substrate without extra steps, for example bonding and notching.

The invention also provides a method for operating an integrated circuit package comprising a transparent substrate having a first surface and a second surface opposite to the first surface, a semiconductor layer formed on the second surface of the transparent substrate, a photosensitive device formed on the semiconductor layer, and a metal plug formed on the semiconductor layer and electrically connected to the photosensitive device. The operation method comprises: sensing light from the first surface of the transparent substrate and the semiconductor layer through a backside of the photosensitive device; producing a signal by the photosensitive device; and transmitting the signal to a solder ball over the second surface of the transparent substrate by the metal plug.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a cross section of a conventional integrated circuit package;

FIGS. 2A through 2E are cross sections illustrating a method for fabricating an integrated circuit package according to an embodiment of the invention; and

FIG. 3 is a flow chart of a method for fabricating an integrated circuit package according to an embodiment of the invention.

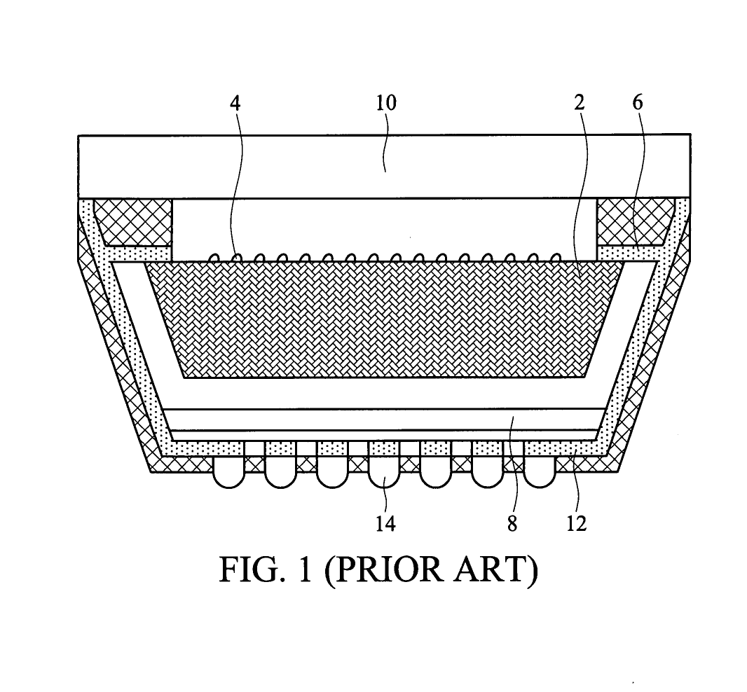

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

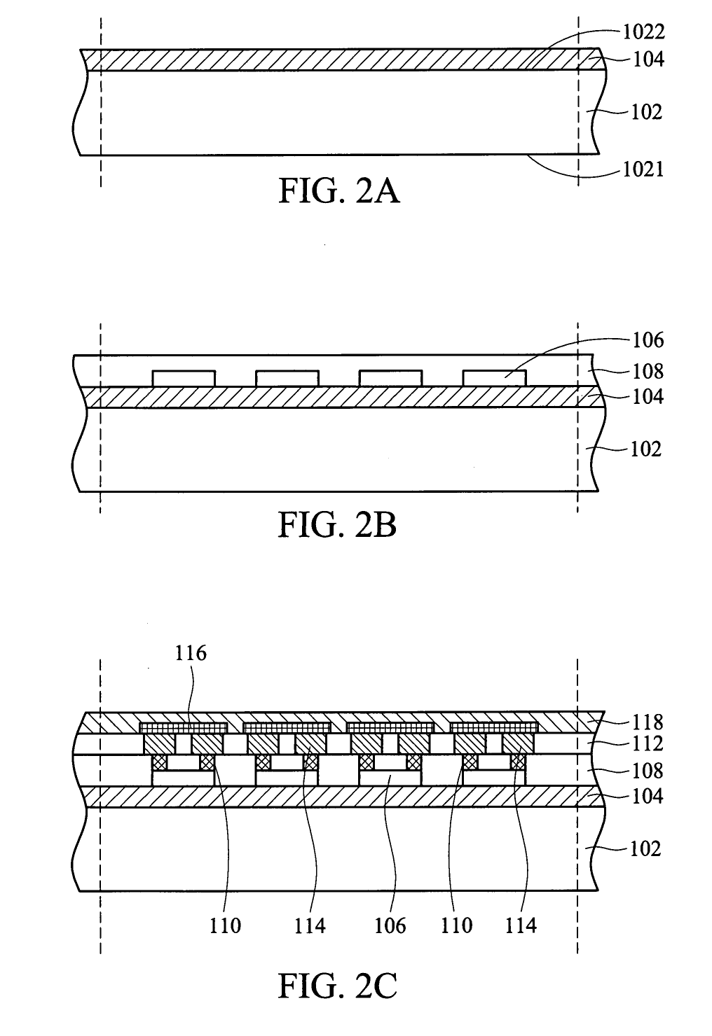

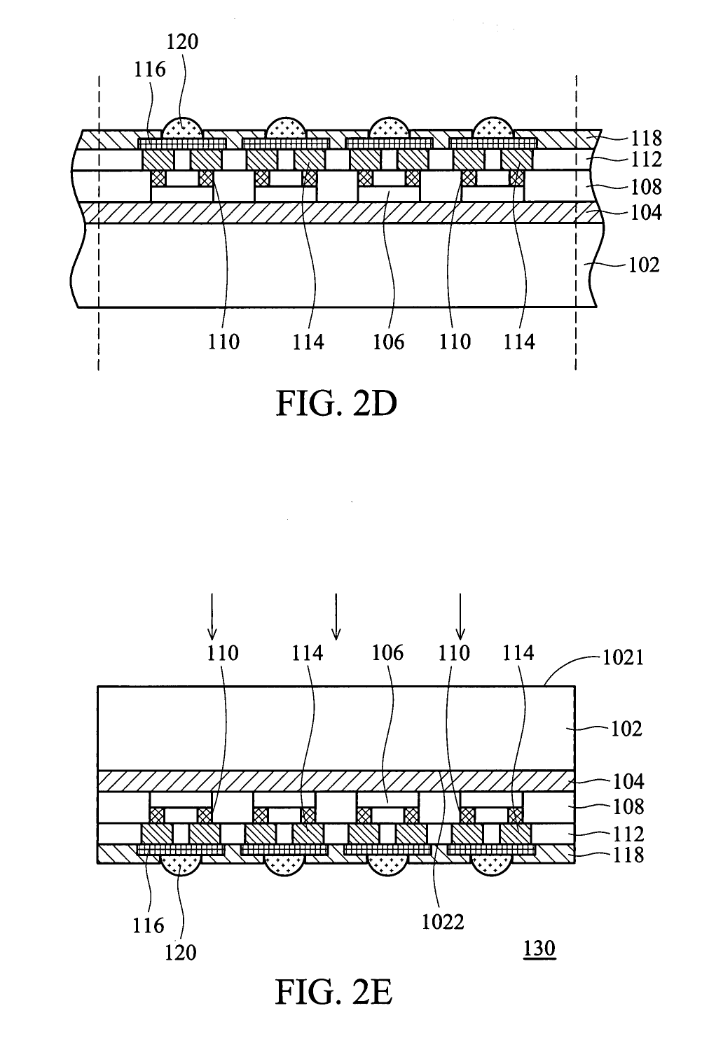

FIGS. 2A through 2E are cross sections illustrating a method for fabricating an integrated circuit package according to an embodiment of the invention. As shown in FIG. 2A, a transparent substrate 102, also referred to as a covering plate, having a first surface 1021 and a second surface 1022 opposite to each other, is provided. Preferably, the transparent substrate 102 is made of a material, for example glass or polymer such as polyester. Note that the first surface 1021 of the transparent substrate 102 may serve as a light incident surface of the integrated circuit package later formed.

In FIG. 2A, a semiconductor layer 104 is deposited on the second surface 1022 of the transparent substrate 102. In some embodiments, the semiconductor layer 104 is formed by a low temperature chemical vapor deposition (low temperature CVD), in which the temperature may be of between about 500° C. and 800° C. Preferably, the semiconductor layer 104 is made of a material such as polysilicon. Moreover, silicon germanium (SiGe) or gallium arsenide (GaAs) can be also used.

In an embodiment, the thickness of the semiconductor layer 104 is between about 0.1 μm and 10 μm, preferably, 3 μm. Note that the semiconductor layer 104 may function as a substrate, on which a photosensitive device is later fabricated, and be utilized as a medium for light penetration thereto. Thus, the thickness of the semiconductor layer 104 with limitations on thickness and thinness to meet functional demands is only required. The thickness of the semiconductor layer 104 is only an exemplary embodiment, and is not limited thereto.

As shown in FIG. 2B, a photosensitive device 106 is fabricated on the semiconductor layer 104. In one embodiment, the photosensitive device 106 is fabricated by, for example a complementary metal oxide semiconductor (CMOS) process. Note that the photosensitive device 106 may comprise a photosensitive diode and a driving circuit electrically connected to each other. The photosensitive diode may sense light and then produce a signal. The signal is transmitted to the driving circuit and is amplified. After amplifying, the signal is then transmitted to an exterior circuit.

Next, an interlayer dielectric (ILD) 108, for example oxide layer, is formed on the second surface 1022 of the transparent substrate 102 by, for example chemical vapor deposition (CVD) to cover the photosensitive device 106.

In FIG. 2C, the metal plug 110 is formed in the interlayer dielectric 108 to electrically connect to the photosensitive device 106. In some embodiments, the interlayer dielectric 108 is patterned by photolithography and etching to form an opening and expose the photosensitive device 106. A metal material layer, for example copper (Cu), aluminum (Al), tungsten (W), or any other suitable material, is deposited over the second surface 1022 of the transparent substrate 102 and is extended to the opening by, for example electrical chemical deposition (ECD), sputtering, evaporation, or any other suitable manner. The metal material layer is removed by chemical mechanical polishing (CMP) process to form the metal plug 110 in the interlayer dielectric 110.

Note that because the sensitive surface of the photosensitive device is disposed opposite to the side where the metal plug is located, greater flexible is given for fabrication and design of the metal plug.

In FIG. 2C, an interlayer dielectric 112 is formed over the second surface 1022 of the transparent substrate 102 followed by forming a metal plug 114 in the interlayer dielectric 112 to electrically connect to the metal plug 110. Formation and material of the metal plug 114 is the same as the metal plug 110. Thus, repeated description will not be provided.

In an alternative embodiment, the interlayer dielectrics 108 and 112 may be formed over the second surface 1022 of the transparent substrate 102. The metal plugs 110 and 114 are formed in the interlayer dielectrics 108 and 112 by, dual damascene process, respectively.

Next, a metal pad 116 such as copper is formed on the interlayer dielectric 112 and electrically connected to the metal plug 114. In one embodiment, a metal material is deposited on the interlayer dielectric 112 followed by patterning the metal material to form the metal pad 116. Note that a conductive path of the signal from the photosensitive device 106 is redistributed by patterning. A solder mask 118 is then coated on the interlayer dielectric 112 and covers the metal pad 116, as shown in FIG. 2C.

In FIG. 2D, a solder ball 120 is formed on the metal pad 116 to electrically connect to the photosensitive device 106. In some embodiments, the solder mask 118 is patterned by photolithography and etching to expose the metal pad 116. A solder material (not shown) is coated on the exposed metal pad 116 and a reflow process is subsequently performed to form the solder ball 120 on the metal pad 116 and electrically connect to the photosensitive device 106 via the metal plug.

Following the above described steps, an individual die is then cut out along the predetermined cutting line thereof by a cutter. Thus, fabrication of an integrated circuit package 130, as shown in FIG. 2E, is complete.

FIG. 2E is a cross section illustrating the integrated circuit package 130 according to an embodiment of the invention. In FIG. 2E, light (as arrows shown in FIG. 2E) penetrates from first surface 1021 of the transparent substrate 102 into the integrated circuit package 130. Specifically, light penetrates the transparent substrate 102 and semiconductor layer 104 to the photosensitive device 106. When the photosensitive device 106 senses light through its backside, a signal is subsequently produced by the photosensitive device 106 and is transmitted to solder ball 120 by, metal plugs 110 and 114, and later to an exterior circuit. Thus, allowing the signal conductive path to be shortened.

For the integrated circuit package, the solder ball may directly electrically connect to the photosensitive device by the metal plug without forming an additional extension pad. Thus, fabrication cost is reduced. Moreover, the dimensions of the integrated circuit package are reduced because an extra carrying plate and an extra silicon substrate, requiring appropriate thicknesses, are not required.

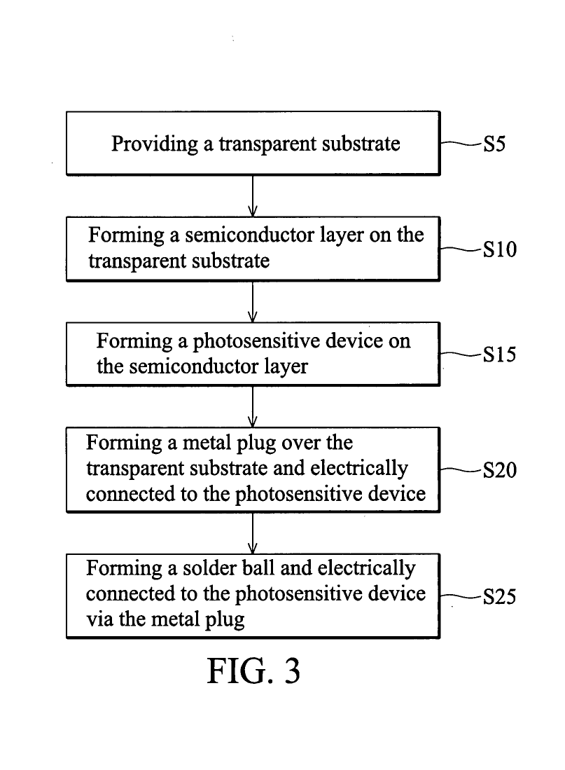

FIG. 3 is a flow chart of a method for fabricating an integrated circuit according to an embodiment of the invention. A transparent substrate is provided, as shown in step S5. Next, a semiconductor layer is formed on the transparent substrate, as shown in step S10. A photosensitive device is then formed on the semiconductor layer, as shown in step S15. Thereafter, a metal plug is formed over the transparent substrate and is electrically connected to the photosensitive device, as shown in step S20. A solder ball is formed and electrically connects to the photosensitive device via the metal plug, as shown in step S25. An individual die is cut out along the predetermined cutting line thereof by a cutter to complete the integrated circuit package.

Note, fabrication and design of the metal plug are flexible as the metal plug is disposed on the opposite surface of the sensitive surface of the photosensitive device. Meanwhile, because the metal pad is patterned, the conductive path of the signal from the photosensitive device is redistributed.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An integrated circuit package, comprising:
a transparent substrate having a first surface and a second surface opposite to the first surface;
a semiconductor layer formed on the second surface of the transparent substrate;
a photosensitive device formed on the semiconductor layer;
a metal plug formed on the second surface of the transparent substrate and electrically connected to the photosensitive device; and
a solder ball formed over the second surface of the transparent substrate and electrically connected to the metal plug.

2. The package as claimed in claim 1, wherein the transparent substrate comprises glass or polymer.

3. The package as claimed in claim 1, wherein the semiconductor layer comprises silicon, gallium arsenide, or silicon germanium.

4. The package as claimed in claim 1, wherein the semiconductor layer has a thickness of between about 0.1 μm and 10 μm.

5. The package as claimed in claim 1, wherein the photosensitive device senses light through its backside opposite to the second surface of the transparent substrate.

6. The package as claimed in claim 1, further comprising an interlayer dielectric formed on the semiconductor layer, wherein the interlayer dielectric surrounds the metal plug.

7. The package as claimed in claim 1, wherein the metal plug comprises copper, tungsten, or aluminum.

8. The package as claimed in claim 1, further comprising:
a metal pad formed over the second surface of the transparent substrate and electrically connected to the metal plug; and
a solder mask covering a portion of the metal pad.

9. The package as claimed in claim 8, wherein the solder ball is located on a portion of the metal pad without covering the solder mask.

10. The package as claimed in claim 1, wherein the integrated circuit package has a light incident surface opposite to a surface the metal plug located.

11. A method for fabricating an integrated circuit package, comprising:
providing a transparent substrate having a first surface and a second surface opposite to the first surface;
forming a semiconductor layer on the second surface of the transparent substrate;
forming a photosensitive device on the semiconductor layer;
forming a metal plug on the second surface of the transparent substrate and electrically connected to the photosensitive device; and
forming a solder ball over the second surface of the transparent substrate and electrically connected to the metal plug.

12. The method as claimed in claim 11, wherein the semiconductor layer is formed by low temperature chemical vapor deposition.

13. The method as claimed in claim 12, wherein the semiconductor layer is formed at a temperature of between about 500° C. and 800° C.

14. The method as claimed in claim 11, further comprising forming an interlayer dielectric on the semiconductor layer and surrounding the metal plug.

15. The method as claimed in claim 11, further comprising:
forming a metal pad over the second surface of the transparent substrate and electrically connected to the metal plug.

16. The method as claimed in claim 15, further comprising:
covering a solder mask on the metal pad; and
patterning the solder mask to expose a portion of the metal pad.

17. The method as claimed in claim 16, wherein the solder ball is located on the exposed metal pad.

18. A method for operating an integrated circuit package comprising a transparent substrate having a first surface and a second surface opposite to the first surface, a semiconductor layer formed on the second surface of the transparent substrate, a photosensitive device formed on the semiconductor layer, and a metal plug formed on the semiconductor layer and electrically connected to the photosensitive device, wherein the method comprising:
sensing light from the first surface of the transparent substrate and the semiconductor layer through a backside of the photosensitive device;
producing a signal by the photosensitive device; and
transmitting the signal to a solder ball over the second surface of the transparent substrate by the metal plug.

19. The method as claimed in claim 18, wherein the backside of the photosensitive device is opposite to the second surface of the transparent substrate.

20. The method as claimed in claim 18, wherein the solder ball is located on the metal plug.
